(19) United States
(12) Patent Application Publication
(10) Pub. No.: US 2025/0046572 A1
(43) Pub. Date: Feb. 6, 2025

(54) A METHOD AND APPARATUS FOR ENHANCING ION ENERGY AND REDUCING ION ENERGY SPREAD IN AN INDUCTIVELY COUPLED PLASMA

(71) Applicant: Lam Research Corporation, Fremont, CA (US)

(72) Inventors: Juline Shoeb, Fremont, CA (US); Myeong Yeol Choi, Campbell, CA (US); Alexander Miller Paterson, San Jose, CA (US); Yuhou Wang, Fremont, CA (US)

(73) Assignee: Lam Research Corporation, Fremont, CA (US)

(21) Appl. No.: 18/693,940

(22) PCT Filed: Sep. 22, 2022
(86) PCT No.: PCT/US2022/076866

§ 371 Date: Mar. 20, 2024

Related U.S. Application Data
(60) Provisional application No. 63/252,040, filed on Oct. 4, 2021.

(51) Int. Cl. H01J 37/32

(52) U.S. Cl. CPC H01J 37/32128; H01J 37/32183; H01J 37/32715; H01J 37/321; H01J 2237/2007; H01J 2237/334

(57) ABSTRACT

A method for operating a plasma chamber to increase ion energy and decrease angular spread of ions during an etch operation is described. Method includes placing a substrate on an electrostatic chuck within the plasma chamber, wherein the electrostatic chuck is electrically coupled to a node. Method further includes forming a plasma in the plasma chamber, where the plasma produces a sheath with a first sheath voltage. The method further includes increasing the first sheath voltage to a second sheath voltage by applying a non-sinusoidal voltage at the electrostatic chuck and by applying a sinusoidal voltage at the electrostatic chuck, where a sum of the non-sinusoidal voltage and the sinusoidal voltage creates a voltage response on the electrostatic chuck that effectuates a change in a spread in ion energy at the wafer.

### CLAIM FOR PRIORITY

This application is a national phase application from PCT Application No. PCT/US2022/076866 filed Sep. 22, 2022, which claims the benefit of priority to U.S. Provisional Patent Application No. 63/252,040, filed on Oct. 4, 2021, titled “METHOD AND APPARATUS FOR ENHANCING ION ENERGY AND REDUCING ION ENERGY SPREAD IN AN INDUCTIVELY COUPLED PLASMA,” and which is incorporated by reference in its entirety.

### BACKGROUND

Substrate processing for etch and deposition forms a backbone of the semiconductor industry. While a variety of plasma processing techniques may be utilized, inductively coupled plasmas provide advantageous features such as multiple ways to control ion energy and ion angular distribution. Controlling ion energy and ion angular distribution can provide a plethora of advantages for etch and deposition. Ion behavior can be controlled by changing parameters that affect bulk plasma properties and by changing electrical parameters (such as bias voltage) on an electrostatic chuck. Among these two control knobs, methods to change electrical parameters on an electrostatic chuck are being constantly being developed to control ion energy and ion angular distribution.

### BRIEF DESCRIPTION OF THE DRAWINGS

FIG. 1 illustrates a schematic of an apparatus including an electrostatic chuck coupled with a filter and a radio frequency matching network at a common node, in accordance with an embodiment of the present disclosure.

FIG. 2 illustrates a schematic of an apparatus including an electrostatic chuck coupled with a continuous wave voltage generator system and a radio frequency voltage generating system at a common node, in accordance with an embodiment of the present disclosure.

FIG. 3 illustrates a schematic of a system including a plasma processing tool including an electrostatic chuck that is coupled with a continuous wave voltage generator system and a radio frequency voltage generating system at a common node, in accordance with an embodiment of the present disclosure.

FIG. 4 illustrates a relationship between the temperature of ions, voltage supplied to the ions, and an angular spread in a sheath region of a plasma, in accordance with an embodiment of the present disclosure.

FIG. 5 illustrates a method of increasing ion energy and reducing ion angular spread, in accordance with an embodiment of the present disclosure.

FIG. 6A illustrates a plot of an applied voltage generated by a continuous wave voltage generator system, in accordance with an embodiment of the present disclosure.

FIG. 6B illustrates a plot of a summation of an applied voltage generated by a continuous wave voltage generator system and an applied voltage generated by a radio frequency voltage generating system, in accordance with an embodiment of the present disclosure.

FIG. 7A illustrates a plot of a resultant induced voltage on a surface of a substrate superimposed with the applied voltage generated by a continuous wave voltage generator system, in accordance with an embodiment of the present disclosure.

FIG. 7B illustrates a plot of a resultant induced voltage on a surface of a substrate superimposed with the applied voltage generated by a continuous wave voltage generator system and the applied voltage generated by a radio frequency voltage generating system, in accordance with an embodiment of the present disclosure.

FIG. 8 illustrates a plot including ion energy distribution functions in a plasma sheath resulting from an applied voltage generated by a continuous wave voltage generator system, resulting from an applied voltage generated by a radio frequency voltage generating system, and resulting from a combination of applied voltages generated by a continuous wave voltage generator system, and by a radio frequency voltage generating system, in accordance with an embodiment of the present disclosure.

FIG. 9A illustrates a plot of an ion energy angular spread resulting from an applied voltage generated by a radio frequency voltage generating system.

FIG. 9B illustrates a plot of an ion energy angular spread in a plasma sheath resulting from an applied voltage generated by a continuous wave voltage generator system.

FIG. 9C illustrates a plot of an ion energy angular spread in a plasma sheath resulting from an applied voltage generated by a continuous wave voltage generator system and by a radio frequency voltage generating system, in accordance with an embodiment of the present disclosure.

FIG. 9D illustrates a plot of an ion energy angular spread in a plasma sheath resulting from an applied voltage generated by a continuous wave voltage generator system and by a radio frequency voltage generating system, in accordance with an embodiment of the present disclosure.

FIG. 10A illustrates a pictorial representation of an etch profile of a trench formed in a silicon substrate due to an ion energy angular spread resulting from an applied voltage generated by a radio frequency voltage generating system.

FIG. 10B illustrates a pictorial representation of an etch profile of a trench formed in a silicon substrate due to an ion energy angular spread resulting from an applied voltage generated by a continuous wave voltage generator system.

FIG. 10C illustrates a pictorial representation of an etch profile of a trench formed in a silicon substrate due to an ion energy angular spread resulting from an applied voltage generated by a continuous wave voltage generator system and by a radio frequency voltage generating system, in accordance with an embodiment of the present disclosure.

FIG. 10D illustrates a pictorial representation of an etch profile of a trench formed in a silicon substrate due to an ion energy angular spread resulting from an applied voltage generated by a continuous wave voltage generator system and by a radio frequency voltage generating system, in accordance with an embodiment of the present disclosure.

FIG. 11 illustrates a processor system with machine-readable storage media having instructions that when executed cause the processor to control spread in ion energy, in accordance with various embodiments.

### DETAILED DESCRIPTION

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

A method and apparatus for enhancing ion energy and reducing ion energy spread in an inductively coupled plasma is described. In the following description, numerous specific details are set forth, such as structural schemes to provide a thorough understanding of embodiments of the present disclosure. It will be apparent to one skilled in the art that embodiments of the present disclosure may be practiced without these specific details. In other instances, well-known features, such as radio frequency sources, are described in lesser detail to not unnecessarily obscure embodiments of the present disclosure. Furthermore, it is to be understood that the various embodiments shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

Unless otherwise specified in the explicit context of their use, the terms “substantially equal,” “about equal” and “approximately equal” mean that there is no more than incidental variation between two things so described. In the art, such variation is typically no more than +/−10% of the referred value.

Inductively coupled plasmas offer distinct advantages over other forms of plasma systems in that ion energies at a substrate can be independently controlled from increasing ion temperatures in the plasma. Ion temperatures can be controlled by a transformer coupling that induces an electric field within an etch chamber. The etch chamber confines the plasma. The induced electric field helps to sustain the plasma and control global parameters such as electron and ion temperatures, densities etc. Plasma etch and deposition systems based on inductively coupled plasmas include an electrostatic chuck that supports wafer or substrate for processing. The wafer comes into contact with a plasma sheath (sheath region) at the edge of a plasma boundary. Typically, ions exit the sheath with a characteristic ion energy and ion angular distribution. The ion energies are typically controlled by a bulk plasma potential but can also be controlled by biasing the electrostatic chuck.

The electrostatic chuck includes a conductive electrode and an insulator layer on the conductive electrode, where the substrate typically rests on the insulator layer. The electrostatic chuck is typically voltage biased by a radio frequency (RF) voltage waveform to induce an RF voltage bias on the substate. The RF voltage bias induced on the substrate overcomes the capacitive effects of the insulator, as well as the ion current on the substrate. The RF voltage bias can help to change an effective voltage within the sheath region.

Changing the effective voltage within the sheath region can advantageously provide a pathway to reduce an angular spread in the ions exiting the plasma. Reducing ion angular spread can be very important for etching high aspect ratio feature sizes during semiconductor device fabrication. An aspect ratio that is greater than 20:1 may be considered to be a high aspect ratio. Ion angular spread is proportional to square root of ion temperature and inversely proportional to square root of sheath voltage Vs. A common approach to reduce ion angular spread is to enhance bias power on the electrostatic chuck. Increasing biasing power increases sheath voltage Vs and reduces ion angular spread. However, if the RF voltage waveform is increased substantially it may generate plasma and may also cause ion temperature Ti to also increase. In such a scenario, effectively reducing ion angular spread becomes challenging. However, when an RF and a DC-like signals are mixed, sheath voltage Vs increases. However, since DC-like signal does not generate as much plasma like RF signal, ion temperature Ti is no longer enhanced. In this manner, mixing RF and DC-like signal can be a feasible way to reduce ion angular spread that etches feature faster and improves feature CD.

A DC-like signal can be super-imposed with a high frequency RF signal to provide a combined voltage pulse. In various embodiments, the DC-like voltage signal includes a non-sinusoidal voltage waveform having frequency range between 400 kHZ and 4000 KHz. A low frequency voltage waveform ensures that the voltage is not blocked by a capacitance of an insulator layer present on the electrostatic chuck. The amplitude of the DC-like voltage signal can also be controlled to provide an effective voltage that overcomes an increase in ion current on the wafer during operation. To contrast RF from DC-like RF, RF voltage is referred to herein as sinusoidal continuous wave voltage, and DC-like is referred to as non-sinusoidal continuous wave voltage.

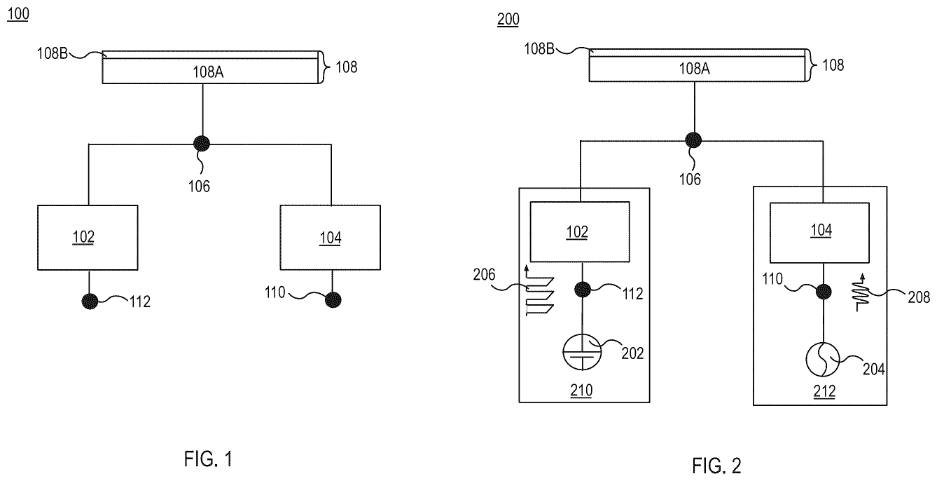

FIG. 1 illustrates a schematic of apparatus 100. Apparatus 100 includes filter 102, radiofrequency (RF) matching network 104 coupled with filter 102 at node 106. Apparatus 100 further includes electrostatic chuck 108 coupled with the filter 102 and RF matching network 104 at node 106. In some embodiments, RF matching network 104 facilitates power delivery at a range between 13.56 MHz and 100 MHz. RF matching network 104 may be coupled to a RF generator (not shown) at node 110.

In some embodiments filter 102 is a notch filter. In some embodiments, the notch filter has a stopband frequency between 12 MHz and 100 MHz. In other embodiments, filter 102 is a low pass filter than has a cut-off frequency of 5 MHz. Filter 102 can prevent signal from RF matching network 104 from damaging any components coupled at node 112. For example, filter 102 may be coupled to a RF generator (not shown) at node 112.

In a simplest embodiment, electrostatic chuck 108 includes an electrode plate 108A coupled with node 106, and insulator 108B on a material of the electrode plate 108A. The insulator 108B may include dielectric materials including alloys and ceramics such as alumina (Al2O3), silicon dioxide (SiO2), silicon nitride (Si3N4), and sapphire.

FIG. 2 illustrates a schematic of apparatus 200. In addition to the elements of apparatus 100 (such as for e.g., filter 102, RF matching network 104, electrostatic chuck 108), apparatus 200 further includes non-sinusoidal continuous wave voltage generator 202 coupled in series with filter 102 at node 112. As shown, filter 102 is in series between non-sinusoidal continuous wave voltage generator 202 and the node 106. Non-sinusoidal continuous wave voltage generator 202 may be configured to produce voltage waveform 206 at electrostatic chuck 108. Voltage waveform 206 may be pulsed, as illustrated in the schematic. In some embodiments, non-sinusoidal continuous wave voltage generator 202 can generate a peak voltage of up to 100 kV. In other embodiments, non-sinusoidal continuous wave voltage generator 202 is configured to produce a voltage in the range of 2 kV to 10 kV. Non-sinusoidal continuous wave voltage generator 202 can generate voltage pulses in the range of 50 kHz and 500 kHz. Filter 102 and non-sinusoidal continuous wave voltage generator 202 may be elements of a non-sinusoidal continuous wave voltage generator system 210, in accordance with an embodiment of the present disclosure.

Apparatus 200 further includes sinusoidal continuous wave voltage waveform generator 204 coupled in series with RF matching network 104 at node 110. As shown, RF matching network 104 is in series between sinusoidal continuous wave voltage waveform generator 204 and node 106. Sinusoidal continuous wave voltage waveform generator 204 is configured to produce voltage waveform 208 at electrostatic chuck 108. Voltage waveform 208 may be pulsed, as illustrated in the schematic. In some embodiments, sinusoidal continuous wave voltage waveform generator 204 can output a peak power of up to 100 kW. Sinusoidal continuous wave voltage waveform generator 204 can generate voltage pulses in the range of 13 MHz-100 MHz. RF matching network 104 and sinusoidal continuous wave voltage waveform generator 204 may be elements of sinusoidal continuous waveform generator system 212, in accordance with an embodiment of the present disclosure.

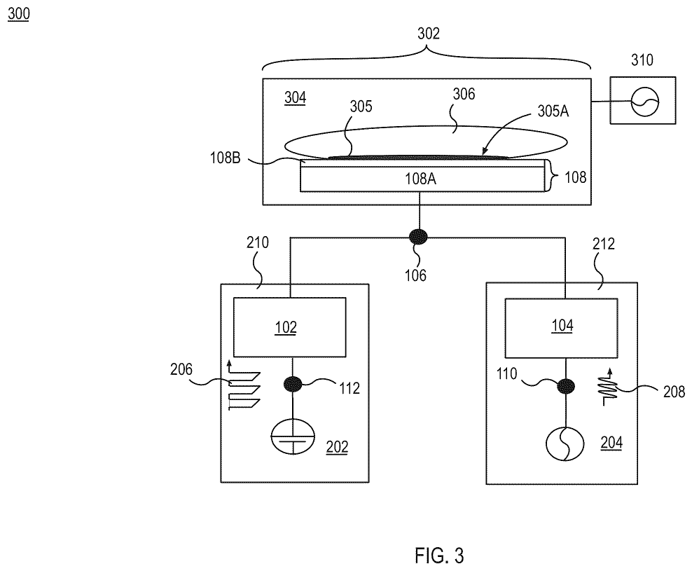

FIG. 3 illustrates a schematic of system 300 including a plasma processing tool 302 including one or more features of apparatus 200 (FIG. 2). In the illustrative embodiment, plasma processing tool 302 is an inductively coupled etch tool 302, that includes electrostatic chuck 108 within process chamber 304 and RF generator 310 coupled with coils above process chamber 304. During operation, plasma 306 is generated within process chamber 304. Ions are ejected from a plasma sheath. Plasma sheath is at an outermost portion of the plasma 306 that is at the vicinity of insulator 108B. The plasma sheath is a non-neutral region formed at a plasma boundary to balance electron and ion losses to maintain quasi-neutrality. Ions that exit the plasma sheath impinge onto substate 305 placed on electrostatic chuck 108 and perform etching (e.g., chemical, mechanical etc.) of one or more materials within substate 305.

As discussed above, the characteristics of the ions (velocity and angular distribution) within the sheath region of plasma 306 depends on (a) plasma potential and (b) potential at surface 305A of substate 305, which may be controlled by a voltage applied to electrostatic chuck 108. In particular, velocity of ions is directly influenced by both (a) and (b) because an increase in both (a) and (b) increases an electric field that drives ions towards electrostatic chuck 108.

In various embodiments, when a sinusoidal continuous wave voltage is applied to the electrostatic chuck 108 by sinusoidal continuous wave voltage waveform generator 204, the plasma sheath oscillates in response to the applied sinusoidal continuous wave voltage. Application of sinusoidal continuous wave voltage changes a width (and potential) of the sheath. Changes in sheath width or sheath boundary is defined by rapid oscillations of electrons at this boundary in response to applied sinusoidal continuous wave voltage. Because ions are significantly less mobile than electrons, ions respond slowly and over a time that is averaged over a frequency of the applied sinusoidal continuous wave voltage. The slower response causes a spread in ion energy distribution. It is to be appreciated that the oscillations in the sheath are due to oscillations arising from an inductive electric field that drives plasma oscillations, as well as from a pulsed voltage waveform 208 that is applied to electrostatic chuck 108. However, for the purposes of influencing ion distribution in inductively coupled plasma systems, pulsed voltage waveform 208 may play a larger role in oscillations.

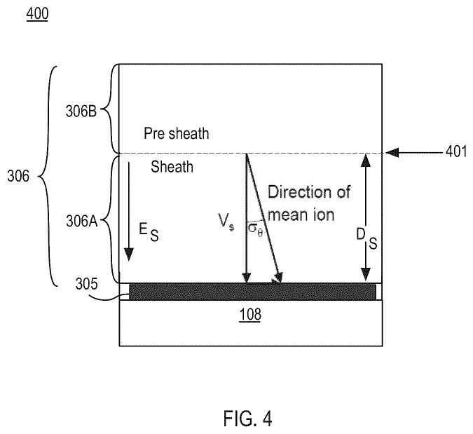

A relationship between the temperature of ions, voltage supplied to the ions, and the angular spread of ions is illustrated in a diagram 400 in FIG. 4. In the illustrative embodiment, plasma 306 includes sheath 306A and presheath 306B adjacent to sheath 306A. The voltage supplied to the ion at boundary 401 between sheath 306A and presheath 306B is related to an electric field in the sheath 306A and a thickness Ds, of the sheath 306A. Electric field Es, arises in the sheath region due to rapid movement of electrons at the boundary 401 and is directly related to the sheath voltage Vs, at the boundary 401 relative to a potential at electrostatic chuck 108. The substrate is not illustrated for clarity. Electric field Es is a function of the power coupled to an etch chamber sustaining the plasma 306. In the illustrative embodiment, electric field Es, is directed towards electrostatic chuck 108. In an embodiment, the lateral component of ion velocity (due to ion temperature Ti) arises from random motion of ions in the plasma. A vector sum of the ion velocity, and sheath voltage Vs provides a maximum ion angular spread, sigma theta.

A relationship between the temperature of ions, voltage supplied to the ions within the sheath, and of the angular spread in ion velocity illustrated in FIG. 4, is expressed by equation 1.1:

$$Sigma theta = {Tan}^{- 1} [ Square root ( {T}_{i} / e {V}_{s} ) ] , \qquad ( 1.1 )$$

where sigma theta is an angular spread, Ti is the temperature of ions, and Vs is a sheath voltage of plasma sheath (of plasma 306) within process chamber 304 (in FIG. 3).

The angular spread theta of ions accelerating towards electrostatic chuck 108, is directly influenced by a ratio between ion temperature Ti and sheath voltage Vs. Thus, methods to increase sheath voltage Vs without increasing plasma potential are highly desirable.

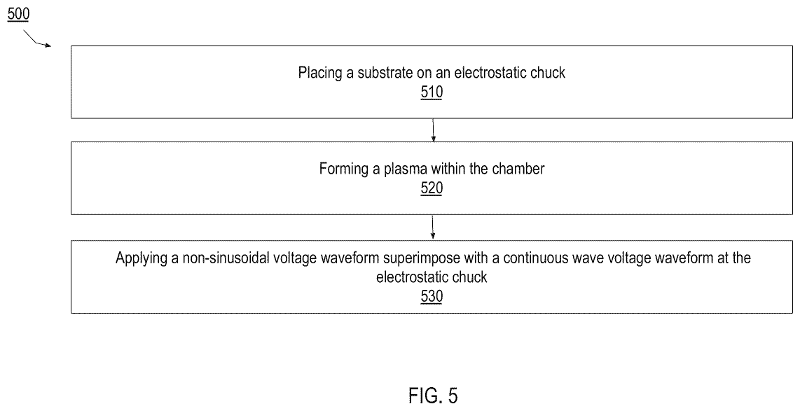

FIG. 5 illustrates method 500 of increasing ion energy and reducing ion angular spread, in accordance with an embodiment of the present disclosure. Some or all operations of method 500 may be performed or controlled by hardware, software, or a combination of them. Method 500 begins at operation 510 by placing a substrate on an electrostatic chuck within a plasma chamber, where the electrostatic chuck is electrically coupled to a node. Method 500 continues at operation 520 by forming a plasma within the plasma chamber, where the plasma produces a sheath with a first sheath voltage. Method 500 concludes at operation 530 by increasing the first sheath voltage to a second sheath voltage by applying a non-sinusoidal voltage waveform including a first periodic function at the electrostatic chuck and applying a continuous wave voltage including a second periodic function at the electrostatic chuck, where a sum of the non-sinusoidal voltage and the sinusoidal voltage effectuates a change in a spread in ion energy at the wafer.

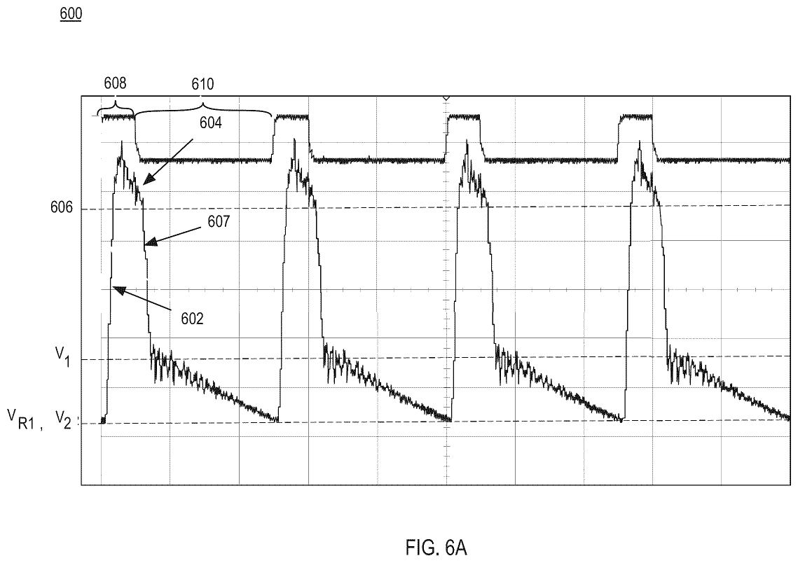

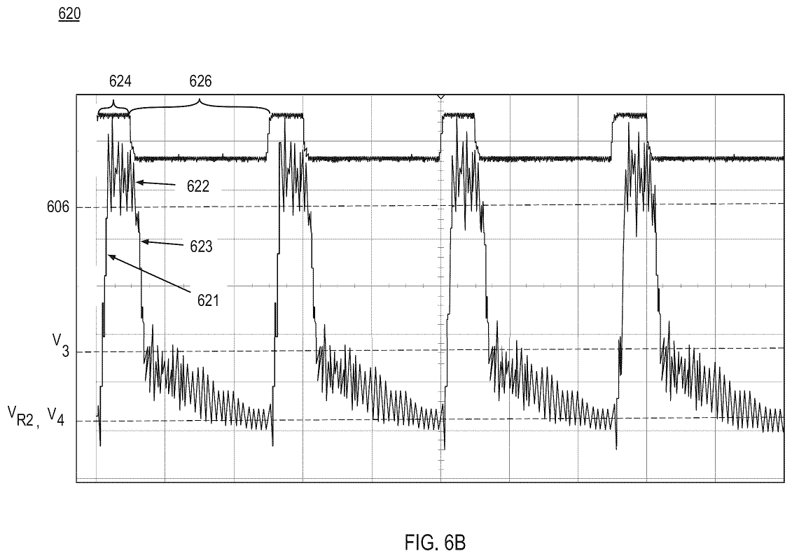

FIG. 6A illustrates plot 600 of voltage waveform 602 generated by a non-sinusoidal waveform generator system, in accordance with an embodiment of the present disclosure. In an embodiment, the non-sinusoidal continuous wave voltage generator system 210 (described in association with FIGS. 2 and 3) may be utilized to generate voltage waveform 602. In an embodiment, the voltage waveform 602 includes one or more harmonics. In some embodiments, each harmonic is an integer multiple of a fundamental frequency such as 400 kHz. In some embodiments, voltage waveform 602 includes up to and including the tenth harmonic (for example 4000 kHz).

In the illustrative embodiment, the voltage waveform 602 comprises a positive pulse portion 604 that is above the zero level 606 and a negative pulse portion 607 comprising a ramp phase. The positive pulse portion is applied for a duration 608 after ramping from a negative reference voltage level, V_{R1}. The duration 608 may last for at least 20 nanoseconds.

The voltage waveform 602 further comprises a quasi-instantaneous ramp down to a negative voltage level, V₁, followed by a ramp down to a second voltage level V₂, where a magnitude of V₂ is greater than a magnitude of V₁. In some embodiments, V₂ is at least 10% greater than V₁. In the illustrative embodiment, V₂ is also the reference voltage level, V_{R1}. The duration 610 of the ramp down from V1 to V₂ is dependent on a desired pulse width. In the illustrative embodiment, the ramp down from V1 to V₂ includes low frequency oscillations from the 400 kHz-4000 kHz because of superposition between the different harmonics described above.

In some embodiments, the pulse width is between 0-2 microseconds. The ramp down to V₂ completes a single cycle of voltage waveform 602. In the illustrative embodiment, the voltage waveform 602 includes repetition of the cycle, where 4 pulses are illustrated. In an embodiment, the duty cycle of voltage waveform 602 is between 0 and 100.

FIG. 6B illustrates plot 620 of voltage waveform 621 generated by a summation of an applied voltage generated by a non-sinusoidal waveform generator system, and an applied voltage generated by a non-sinusoidal continuous wave voltage waveform generator, in accordance with an embodiment of the present disclosure. In an embodiment, non-sinusoidal continuous wave voltage generator 202 and sinusoidal continuous waveform generator system 212, (described in association with FIGS. 2 and 3 may be utilized to generate voltage waveform 621. In some embodiments, voltage waveform 621 includes one or more features of voltage waveform 602 and a super position of a sinusoidal voltage pulse generated by sinusoidal continuous wave voltage waveform generator 204 (FIG. 2). In some embodiments, sinusoidal continuous wave voltage waveform generator 204 utilized can output a peak power of up to 100 kW and generate a voltage waveform in the range of 10 MHz-100 MHz. In the illustrative embodiment, a peak sinusoidal continuous wave voltage is less than a negative non-sinusoidal continuous wave voltage on the surface of the substrate (or wafer). The instantaneous voltage does not become positive during a negative voltage period of non-sinusoidal wave voltage signal, i.e., |Vsinusoidal|<|Vnon-sinusoidal|.

In the illustrative embodiment, voltage waveform 621 comprises a positive pulse portion 622 that is above zero level 606 (dashed lines) and a negative pulse portion 623, where negative pulse portion 623 comprises a ramp phase. The positive pulse portion 622 is applied for a duration 624 after ramping from a negative reference voltage level, V_{R2}. Duration 624 may last at least 100 ns but less 1 ms. In contrast to voltage waveform 602, voltage waveform 621 includes oscillations from the sinusoidal continuous voltage waveform generated by the RF generator (such as sinusoidal continuous wave voltage waveform generator 204 in FIG. 2). The oscillations and finite power add to voltage level of voltage waveform 602.

Voltage waveform 621 further comprises a quasi-instantaneous ramp down to a negative voltage level V3, followed by a ramp down to a second voltage level V4, where a magnitude of V4 is greater than a magnitude of V3. In an embodiment, magnitude of V4 is greater than a magnitude of V3 by at least 10%. In the illustrative embodiment, V4 is also the reference voltage level, V_{R2}. Duration 626 of the ramp down from V3 to V4 is dependent on a desired pulse width. In the illustrative embodiment, the ramp down from V3 to V4 include oscillations from the sinusoidal continuous voltage waveform generated by the RF generator (such as sinusoidal continuous wave voltage waveform generator 204 in FIG. 2). The oscillations amplify the resulting voltage during the positive pulse phase (duration 624) and ramp down phase (duration 626). Duration 626 may last for at least 100 ns but less 1 ms. In an embodiment, the duty cycle of voltage waveform 621 is between 0 and 100.

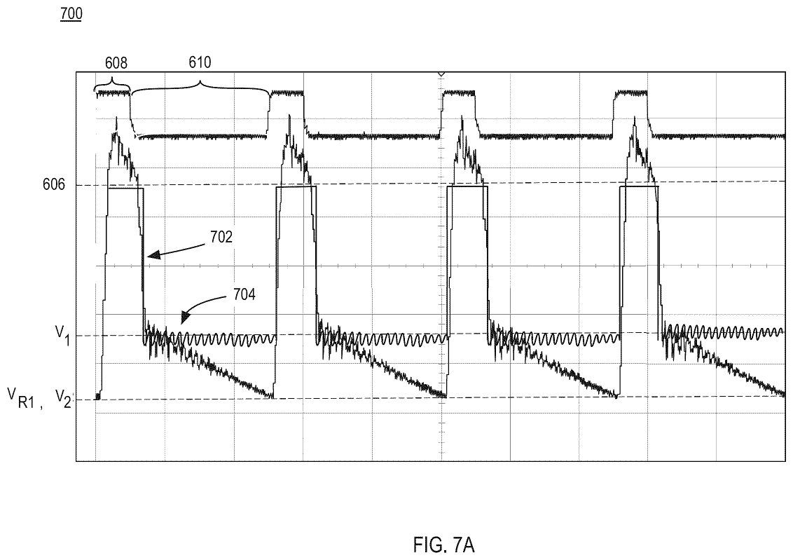

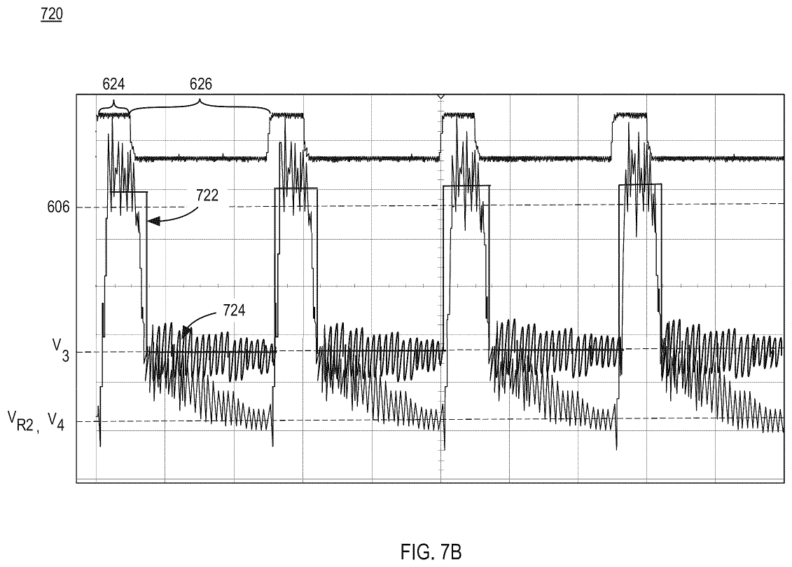

FIG. 7A illustrates a plot 700 of voltage waveform 702 induced on a surface of a substrate (such substate 305 in FIG. 3). Voltage waveform 702 is a result of a super position on the voltage waveform 602 and a voltage induced by ions leaving a sheath and impinging on surface of substrate 305 (FIG. 4). Oscillations in voltage waveform 702 includes low frequency oscillations 704. Low frequency oscillations 704 may range from 400 kHz-4000 kHz because of super position between the different harmonics described above. The voltage waveform 602 generated by a non-sinusoidal continuous wave voltage generator system is superimposed for comparison.

FIG. 7B illustrates a plot 720 of an induced voltage waveform 722 on a surface of a substrate (such as substate 305 in FIG. 3). Induced voltage waveform 722 is a result of a superposition of voltage waveform 621 (FIG. 6B) and a voltage induced by ions leaving a sheath (FIG. 4) impinging on surface of substrate. The oscillations include a sum of low frequency oscillations, described above, and high frequency RF oscillation 724. The applied voltage waveform 602 generated by a sinusoidal continuous wave voltage generator system and the applied voltage generated by a sinusoidal continuous wave voltage generating system is superimposed for comparison.

As discussed above, with regards to FIG. 4 and equation 1.1, an increase in Vs, can be brought about by increasing the voltage applied to the electrostatic chuck. The imposition of a non-sinusoidal continuous waveform to a sinusoidal continuous waveform (such as is illustrated in FIG. 6B) provides additional voltage bias to the sheath voltage Vs, by altering the potential at the wafer surface. An increase in the plasma sheath voltage Vs from a first voltage to a higher second voltage increases the denominator in equation (1.1) and may reduce sigma theta. A reduction in sigma theta may reduce the angular spread in the ion energy.

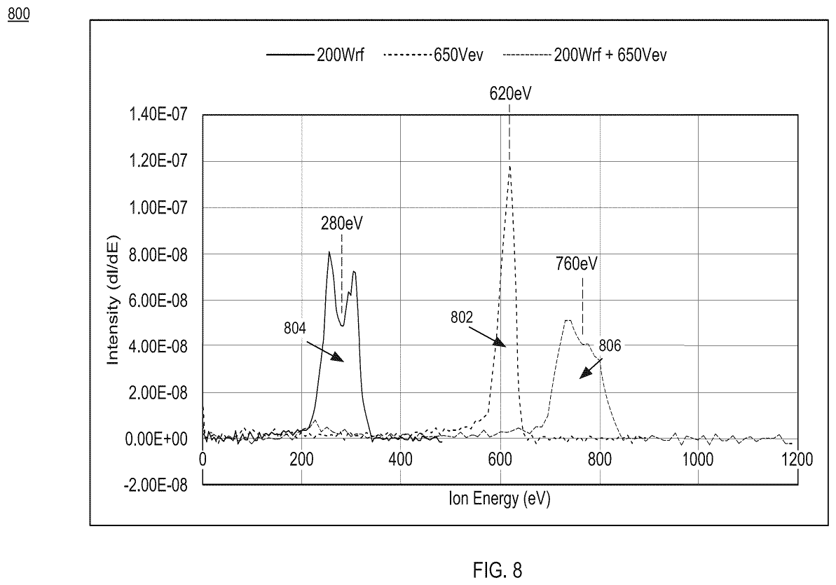

FIG. 8 illustrates plot 800 including ion energy distribution functions (IEDF) in a sheath (such as sheath 306A in FIG. 4) resulting from combination of an applied non-sinusoidal continuous voltage waveform, and an applied sinusoidal continuous voltage waveform, in accordance with an embodiment of the present disclosure.

IEDF 802 is representative of an ion energy distribution in a plasma corresponding to an embodiment, where non-sinusoidal continuous voltage waveform is applied to an electrostatic chuck. In the illustrative embodiment, an ion energy distribution centered around 620 eV is resultant at an electrostatic chuck (such as electrostatic chuck 108 in FIG. 4).

IEDF 804 is representative of an ion energy distribution in a plasma corresponding to an embodiment where a sinusoidal continuous voltage waveform is applied to an electrostatic chuck (such as electrostatic chuck 108 in FIG. 4). In the illustrative embodiment, an ion energy distribution centered around 280 eV is resultant at the electrostatic chuck (such as electrostatic chuck 108 in FIG. 4). The ion energy distribution has bimodal behavior since sheath voltage swings from a low voltage to high voltage. The bi-modal energy distribution is representative of the sensitivity of the ions to a maxima and minima in the sheath voltage swings and a corresponding energy level associated with the maxima and minima voltage levels.

The IEDF 806 is representative of an ion energy distribution in a plasma corresponding to an embodiment where a combination of non-sinusoidal continuous voltage waveform (utilized to generate IEDF 802), and sinusoidal continuous voltage waveform (utilized to generate IEDF 804) is applied simultaneously. In the illustrative embodiment, an ion energy distribution centered around 760 eV is resultant at an electrostatic chuck. IEDF 806 is representative of a substantially non-bi modal distribution since the RF signal is no longer a pure RF but a sinusoidal signal swinging on a reference DC signal. A narrow IEDF may bring substantial improvement in etch selectivity, for example between etching dielectric such as silicon oxide or silicon carbide, and silicon in fluorocarbon gas mixtures. In an embodiment, the total ion energy may be substantially equal to a sum of the ion energy in IEDF 802 and IEDF 804. Enhancement of ion energy and reduction in ion energy angular distribution angle can increase etch rate, improve CD and provide better loading.

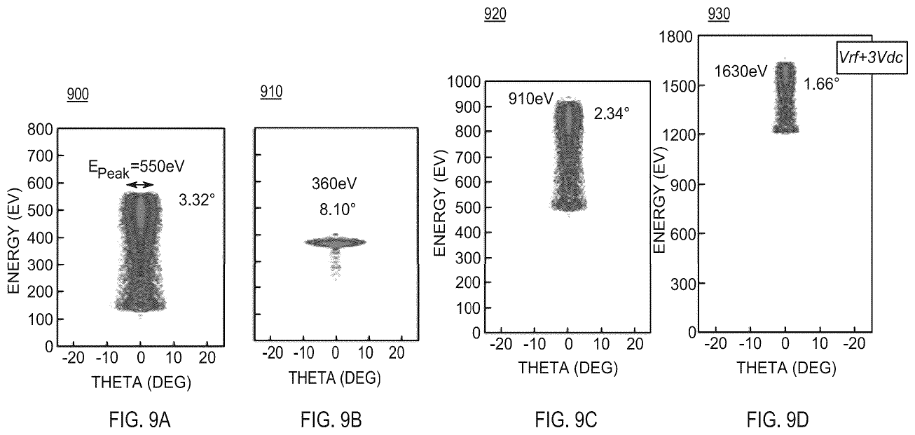

FIGS. 9A-9D are illustrative embodiments of peak energy angular spread corresponding to particular values of applied voltages.

FIG. 9A illustrates a plot 900 of an ion energy angular spread resulting from an applied voltage of 330V generated by a sinusoidal voltage generator (such as sinusoidal continuous wave voltage waveform generator 204 in FIG. 2) that produces a peak energy of 550 eV. In the illustrative embodiment, an ion energy angular spread is approximately 3.32 degrees for a peak ion energy of 550 eV. In general, a sinusoidal bias voltage V_{b}, produces 1.6-1.8*Vb eV peak energy.

FIG. 9B illustrates a plot 910 of an ion energy angular spread resulting from an applied voltage of 360V generated by a non-sinusoidal continuous wave voltage generator (such as non-sinusoidal continuous wave voltage generator 202 in FIG. 2). In the illustrative embodiment, an ion energy angular spread is approximately 8.1 degree for a peak applied voltage of 360V. In general, a non-sinusoidal bias voltage, V_{b-ns}, produces approximately 1V_{b-ns} eV peak energy.

FIG. 9C illustrates a plot 920 of an ion energy angular spread in a plasma sheath resulting from a summation of an applied voltage generated by a non-sinusoidal continuous wave voltage generator and a sinusoidal continuous wave voltage generator, in accordance with an embodiment of the present disclosure. In the illustrative embodiment, ion energy angular spread is resultant from a summation of a 330V applied voltage producing 550 eV peak energy (such as is generated by sinusoidal continuous wave voltage waveform generator 204 in FIG. 2) and a 360V applied voltage (such as is generated by non-sinusoidal continuous wave voltage generator 202 in FIG. 2). In the illustrative embodiment, an ion angle spread is approximately 2.34 degree for a peak applied voltage of 910V. In the illustrative embodiment, the ion energy spread results in a reduction of ion angular spread of almost 30% compared to the ion angular spread in plot 900 (FIG. 9A), and a reduction of ion angular spread of almost 70 percent compared to the ion angular spread in plot 910 (FIG. 9B).

FIG. 9D illustrates a plot 930 of an ion energy angular spread in a plasma sheath resulting from a summation of an applied voltage generated by a non-sinusoidal continuous wave voltage generator and a sinusoidal continuous wave voltage generator, in accordance with an embodiment of the present disclosure. In the illustrative embodiment, ion energy angular spread is resultant from a summation of a 330V applied voltage producing 550 eV peak energy (such as is generated by sinusoidal continuous wave voltage waveform generator 204 in FIG. 2) and a 1080V applied voltage (such as is generated by non-sinusoidal continuous wave voltage generator 202 in FIG. 2). In the illustrative embodiment, an ion angle spread is approximately 1.66 degree for a peak applied voltage of 1630V. In the illustrative embodiment, the ion energy angular spread results in a reduction of ion angular spread of almost 50% compared to the ion angular spread in plot 900 (FIG. 9A), and a reduction of ion angular spread of almost 80 percent compared to the ion angular spread in plot 910 (FIG. 9B).

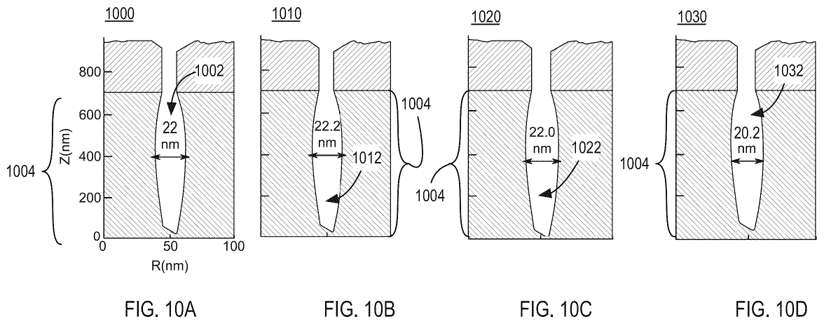

FIG. 10A illustrates a pictorial representation 1000 of an etch profile of trench 1002 formed in silicon substrate 1004 due to an ion energy angular spread described in association with FIG. 9A. In an embodiment, trench 1002 has an initial mask opening of 10 nm. The trench 1002 has a maximum width of 22 nm resulting from a peak ion energy distribution of 3.32 degrees.

FIG. 10B illustrates a pictorial representation 1010 of an etch profile of trench 1012 formed in a silicon substrate 1004 due to an ion energy angular spread described in association with FIG. 9B. In an embodiment, trench 1012 has an initial mask opening of 10 nm. Trench 1002 has a maximum width of 22.2 nm resulting from a peak ion energy distribution of 8.1 degrees. The etch time to pattern trench 1012 is greater than an etch time required to pattern trench 1012 (FIG. 10A), by approximately 5%.

FIG. 10C illustrates a pictorial representation 1020 of an etch profile of trench 1022 formed in silicon substrate 1004 due to an ion energy angular spread described in association with FIG. 9C. In an embodiment, trench 1022 has an initial mask opening of 10 nm. Trench 1022 has a maximum width of 22.0 nm resulting from a peak ion energy distribution of 2.34 degrees. The etch time to pattern trench 1022 is less than an etch time required to pattern trench 1002 (FIG. 10A), by over 25%, i.e., an increase in etch rate of over 34%.

FIG. 10D is a pictorial representation 1030 of an etch profile of a trench 1032 formed in a silicon substrate 1004 due to an ion energy angular spread (described in association with FIG. 9D). In an embodiment, the trench 1032 has an initial mask opening of 10 nm. Trench 1032 has a maximum width of 20.2 nm resulting from a peak ion energy distribution of 1.66 degrees. The etch time to pattern trench 1032 is less than an etch time required to pattern trench 1002 (FIG. 10A), by approximately 50%, i.e., an increase in etch rate of over 90%.

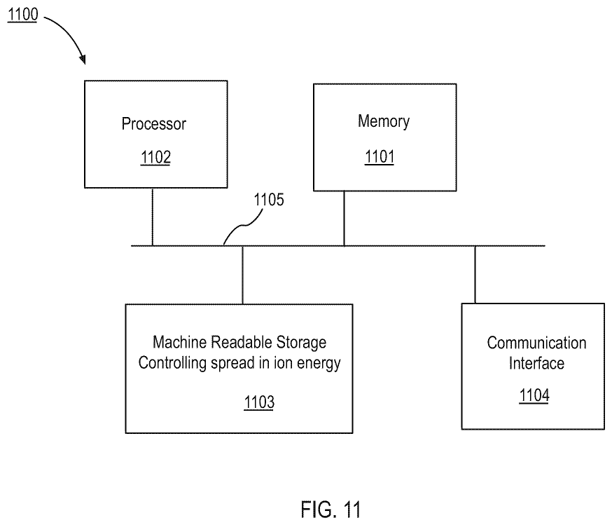

FIG. 11 illustrates processor system 1100 with machine-readable storage media having instructions that when executed cause the processor to enhance ion energy and reduce ion energy spread in an inductively coupled plasma, in accordance with various embodiments. Processes described in various embodiments of the present disclosure may be stored in a machine-readable medium (e.g., 1103) as computer-executable instructions. In some embodiments, processor system 1100 comprises memory 1101, processor 1102, machine-readable storage media 1103 (also referred to as tangible machine-readable medium), communication interface 1104 (e.g., wireless or wired interface), and network bus 1105 coupled together as shown.

In some embodiments, processor 1102 is a Digital Signal Processor (DSP), an Application Specific Integrated Circuit (ASIC), a general-purpose Central Processing Unit (CPU), or a low power logic implementing a simple finite state machine to perform various processes described herein.

In some embodiments, the various logic blocks of processor system 1100 are coupled together via network bus 1105. Any suitable protocol may be used to implement network bus 1105. In some embodiments, machine-readable storage medium 1103 includes instructions (also referred to as the program software code/instructions) for enhancing ion energy and reducing ion energy angular spread in an inductively coupled plasma as described above with reference to various embodiments.

In one example, machine-readable storage media 1103 is a machine-readable storage media with instructions for enhancing ion energy and reducing ion energy angular spread in an inductively coupled plasma. Machine-readable medium 1103 has machine-readable instructions, that when executed, cause processor 1102 to perform the method of measuring and/or reporting as discussed with reference to various embodiments.

Program software code/instructions associated with various embodiments may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In some embodiments, the program software code/instructions associated with processes of various embodiments are executed by processor system 1100.

In some embodiments, the program software code/instructions associated with various embodiments are stored in a machine-readable storage media 1103 and executed by processor 1102. Here, computer executable machine-readable storage media 1103 is a tangible machine-readable medium that can be used to store program software code/instructions and data that, when executed by a computing device, causes one or more processors (e.g., processor 1102) to perform a process. In some embodiments, the process may comprise controlling a pulsed voltage. In some embodiments, the process may comprise controlling a periodic voltage. In some embodiments, the process may comprise modulating a spread in ion energy within a sheath region of a plasma by combining the pulsed voltage and the period voltage. In various embodiments, the sheath region is adjacent to a substrate on an electrostatic chuck. In some embodiments, the pulsed voltage has a frequency lower than a frequency of the periodic voltage.

The tangible machine-readable storage media 1103 may include storage of the executable software program code/instructions and data in various tangible locations, including for example ROM, volatile RAM, non-volatile memory and/or cache and/or other tangible memory as referenced in the present application. Portions of this program software code/instructions and/or data may be stored in any one of these storage and memory devices. In some embodiments, the program software code/instructions can be obtained from other storage, including, e.g., through centralized servers or peer to peer networks and the like, including the Internet. Different portions of the software program code/instructions and data can be obtained at different times and in different communication sessions or in the same communication session.

The software program code/instructions associated with the various embodiments can be obtained in their entirety prior to the execution of a respective software program or application. Alternatively, portions of the software program code/instructions and data can be obtained dynamically, e.g., just in time, when needed for execution. Alternatively, some combination of these ways of obtaining the software program code/instructions and data may occur, e.g., for different applications, components, programs, objects, modules, routines or other sequences of instructions or organization of sequences of instructions, by way of example. Thus, it is not required that the data and instructions be on a tangible machine-readable medium in entirety at a particular instance of time.

Examples of tangible machine-readable storage media 1103 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs), etc.), among others. The software program code/instructions may be temporarily stored in digital tangible communication links while implementing electrical, optical, acoustical, or other forms of propagating signals, such as carrier waves, infrared signals, digital signals, etc. through such tangible communication links.

Example 1: An apparatus comprising: a filter; an RF matching network coupled with the filter at a node; and an electrostatic chuck coupled with the filter and the RF matching network at the node.

Example 2: The apparatus of example 1, wherein the filter is a notch filter, and wherein the notch filter is coupled to a non-sinusoidal voltage waveform source.

Example 3: The apparatus of example 2, wherein the notch filter comprises a stopband frequency between 12 MHz and 100 MHz.

Example 4: The apparatus of example 1, wherein the filter is a low pass filter, wherein the low pass filter is coupled to a DC source.

Example 5: The apparatus of example 4, wherein the low pass filter comprises a cutoff frequency of less than 5 MHz.

Example 6: The apparatus of example 2, wherein the non-sinusoidal voltage waveform source outputs a voltage signal in a range between 400 KHz and 4000 kHz.

Example 7: The apparatus of example 1, wherein the RF matching network is coupled to a sinusoidal voltage waveform generator.

Example 8: The apparatus of example 7, wherein the RF matching network facilitates power delivery of up to 100 kV.

Example 9: The apparatus of example 1, wherein the RF matching network facilitates power delivery at a range between 13.56 MHz and 100 MHz.

Example 10: The apparatus of example 1, wherein the electrostatic chuck comprises a conductive plate and an insulative layer on the conductive plate.

Example 11: An apparatus comprising: a filter; an RF matching network coupled with the filter at a node; an electrostatic chuck coupled with the filter and the RF matching network at the node; a non-sinusoidal voltage waveform generator configured to produce a first pulsed voltage waveform at the electrostatic chuck, wherein the filter is in series between the non-sinusoidal voltage waveform generator and the node; and a sinusoidal voltage waveform generator configured to produce a second pulsed voltage waveform at the electrostatic chuck, wherein the RF matching network is in series between the sinusoidal voltage waveform generator and the node.

Example 12: The apparatus of example 11, wherein the sinusoidal voltage waveform generator produces power at 13.56 MHz to 100 MHz, at a power range between 0-100 kW.

Example 13: The apparatus of example 11, wherein the non-sinusoidal voltage waveform generator is configured to operate between 400 KHz-4000 kHz with a voltage output between 5-10 kV.

Example 14: The apparatus of example 11, wherein the electrostatic chuck comprises a conductive plate and an insulative layer on the conductive plate.

Example 15: A system comprising: a plasma etch chamber configured to produce and confine a plasma; an RF generator coupled with the plasma etch chamber; an electrostatic chuck at a base portion of the plasma etch chamber, the electrostatic chuck electrically coupled to a node, wherein the electrostatic chuck is configured to mechanically support a substrate; a non-sinusoidal voltage waveform generating system electrically coupled to the node, wherein the non-sinusoidal voltage waveform generating system is configured to produce a first pulsed voltage waveform at the electrostatic chuck; and a sinusoidal voltage waveform generating system electrically coupled to the node, wherein the RF generator is configured to produce a second pulsed voltage waveform at the electrostatic chuck.

Example 16: The system of example 15, wherein the non-sinusoidal voltage waveform generating system further comprises a non-sinusoidal voltage waveform generator configured to operate between 400 KHz-4000 kHz with a voltage output between 5-10 kV, and a filter in series.

Example 17: The system of example 15, wherein the sinusoidal voltage waveform generating system further comprises a sinusoidal voltage waveform generator configured to produce power at 13.56 MHz to 100 MHz, at a power range between 0-100 kW and an RF matching network.

Example 18: A method for operating a plasma chamber to increase ion energy and decrease angular spread of ions directed towards a surface of a substrate during an etch operation, the method comprising: placing a substrate on an electrostatic chuck within the plasma chamber, wherein the electrostatic chuck is electrically coupled to a node; forming a plasma in the plasma chamber, wherein the plasma produces a sheath with a first sheath voltage; and increasing the first sheath voltage to a second sheath voltage by applying a non-sinusoidal voltage waveform comprising a first periodic function at the electrostatic chuck and by applying a sinusoidal voltage waveform comprising a second periodic function at the electrostatic chuck, wherein a sum of the non-sinusoidal voltage waveform and the sinusoidal voltage waveform creates a voltage response on the electrostatic chuck that effectuates a change in a spread in the ion energy at the substrate.

Example 19: The method of example 18, wherein applying the non-sinusoidal voltage waveform comprises generating the non-sinusoidal voltage waveform comprising a plurality of harmonics.

Example 20: The method of example 19 wherein the plurality of harmonics includes a 400 kHz fundamental harmonic and up and including to 10^{th} harmonic.

Example 21: The method of example 18, wherein applying the non-sinusoidal voltage waveform further comprises: a positive period, a negative period, duty cycle between 0-100.

Example 22: The method of example 18, wherein applying the non-sinusoidal voltage waveform further comprises: a first negative voltage and a ramp to a second negative voltage, wherein the second negative voltage is at least 10% greater than the first negative voltage.

Example 23: The method of example 18, wherein applying the second periodic function further comprises generating a high frequency pulse at a range between 13.56 MHz and 100 MHz.

Example 24: The method of example 18, wherein applying the second periodic function further comprises generating the sinusoidal voltage waveform having a maximum amplitude of less than 100 kV.

Example 25: The method of example 23, comprising preventing a high frequency signal arriving at the node by blocking frequencies between 12 MHz and 100 MHz.

Example 26. The method of example 23, comprising: generating a resultant voltage from a combination of the high frequency pulse and the sinusoidal voltage waveform; and modulating an ion angular distribution at the substrate using the resultant voltage.

Example 27. The method of example 18, wherein the sinusoidal voltage waveform comprises a first value, wherein the non-sinusoidal voltage waveform comprises a second value, wherein a combination of the first value and the second value results in a first ion angular distribution.

Example 28. The method of example 27, wherein the first ion angular distribution is less than 30 percent of a second ion angular distribution produced by the non-sinusoidal voltage waveform comprising the first value alone.

Example 29. The method of example 27, wherein the first ion angular distribution is less than 70 percent of a third ion angular distribution produced by the non-sinusoidal voltage waveform comprising the second value alone.

Example 30. The method of example 27, wherein the first ion angular distribution creates an etch rate that is 2X an etch rate that would have been produced by the non-sinusoidal voltage waveform alone.

Example 31. A machine-readable storage media having machine executable instructions, that when executed, cause one or more machines to perform a method comprising: controlling a pulsed voltage; controlling a periodic voltage; and modulating a spread in ion energy within a sheath region of a plasma by combining the pulsed voltage and the period voltage, wherein the sheath region is adjacent to a substrate on an electrostatic chuck.

Example 32. The machine-readable storage media of example 31, wherein the pulsed voltage has a frequency lower than a frequency of the periodic voltage.

Example 33. A method for operating a plasma chamber to increase ion energy and decrease angular spread of ions directed towards a surface of a substrate during operation, the method comprising: placing a substrate on an electrostatic chuck within the plasma chamber, wherein the electrostatic chuck is electrically coupled to a node; forming a plasma in the plasma chamber, wherein the plasma produces a sheath with a first sheath voltage; increasing the first sheath voltage to a second sheath voltage by applying a non-sinusoidal voltage waveform comprising a first periodic function at the electrostatic chuck and by applying a sinusoidal voltage waveform comprising a second periodic function at the electrostatic chuck, wherein a sum of the non-sinusoidal voltage waveform and the sinusoidal voltage waveform creates a voltage response on the electrostatic chuck that effectuates a change in a spread in ion energy at the wafer.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the invention should be measured solely by reference to the claims that follow.

1-33. (canceled)

34. An apparatus comprising:
a filter;
an RF matching network coupled with the filter at a node; and
an electrostatic chuck coupled with the filter and a sinusoidal voltage waveform matching network at the node.

35. The apparatus of claim 34, wherein the filter is a notch filter, wherein the notch filter is coupled to a non-sinusoidal voltage waveform source.

36. The apparatus of claim 35, wherein the notch filter comprises a stopband frequency between 12 MHz and 100 MHz.

37. The apparatus of claim 34, wherein the filter is a low pass filter, wherein the low pass filter is coupled to a DC source.

38. The apparatus of claim 37, wherein the low pass filter comprises a cutoff frequency of less than 5 MHz.

39. The apparatus of claim 35, wherein the non-sinusoidal voltage waveform source outputs a voltage signal in a range between 400 kHz and 4000 kHz.

40. The apparatus of claim 34, wherein the sinusoidal voltage waveform matching network is coupled to a sinusoidal voltage waveform generator.

41. The apparatus of claim 40, wherein the RF matching network facilitates power delivery of up to 100 kV.

42. The apparatus of claim 34, wherein the RF matching network facilitates power delivery at a range between 13.56 MHz and 100 MHz.

43. The apparatus of claim 34, wherein the electrostatic chuck comprises a conductive plate and an insulative layer on the conductive plate.

44. An apparatus comprising:
a filter;
an RF matching network coupled with the filter at a node;
an electrostatic chuck coupled wi15th the filter and a sinusoidal voltage waveform matching network at the node;
a non-sinusoidal voltage waveform generator configured to produce a first pulsed voltage waveform at the electrostatic chuck, wherein the filter is in series between the non-sinusoidal voltage waveform generator and the node; and
a sinusoidal voltage waveform generator configured to produce a second pulsed voltage waveform at the electrostatic chuck, wherein the RF matching network is in series between the sinusoidal voltage waveform generator and the node.

45. The apparatus of claim 44, wherein the sinusoidal voltage waveform generator produces power at 13.56 MHz to 100 MHz, at a power range between 0-100 kW.

46. The apparatus of claim 44, wherein the non-sinusoidal voltage waveform generator is configured to operate between 400 kHz-4000 kHz with a voltage output between 5-10 kV.

47. The apparatus of claim 44, wherein the electrostatic chuck comprises a conductive plate and an insulative layer on the conductive plate.

48. A system comprising:
a plasma etch chamber configured to produce and contain a plasma;
an RF generator coupled with the plasma etch chamber;
an electrostatic chuck at a base portion of the plasma etch chamber, the electrostatic chuck electrically coupled to a node, wherein the electrostatic chuck is configured to mechanically support a substrate;
a non-sinusoidal voltage waveform generating system electrically coupled to the node, wherein the non-sinusoidal voltage waveform generating system is configured to produce a first pulsed voltage waveform at the electrostatic chuck; and
a sinusoidal voltage waveform generating system electrically coupled to the node, wherein the RF generator is configured to produce a second pulsed voltage waveform at the electrostatic chuck.

49. The system of claim 48, wherein the non-sinusoidal voltage waveform generating system further comprises a non-sinusoidal voltage waveform generator configured to operate between 400 kHz-4000 kHz with a voltage output between 5-10 kV, and a filter in series.

50. The system of claim 48, wherein the sinusoidal voltage waveform generating system further comprises a sinusoidal voltage waveform generator configured to produce power at 13.56 MHz to 100 MHz, at a power range between 0-100 kW and an RF matching network.

51. A method for operating a plasma chamber to increase ion energy and decrease angular spread of ions directed towards a surface of a substrate during an etch operation, the method comprising:
placing the substrate on an electrostatic chuck within the plasma chamber, wherein the electrostatic chuck is electrically coupled to a node;
forming a plasma in the plasma chamber, wherein the plasma produces a sheath with a first sheath voltage; and
increasing the first sheath voltage to a second sheath voltage by applying a non-sinusoidal voltage waveform comprising a first periodic function at the electrostatic chuck and by applying a sinusoidal voltage waveform comprising a second periodic function at the electrostatic chuck, wherein a sum of the non-sinusoidal voltage waveform and the sinusoidal voltage waveform creates a voltage response on the electrostatic chuck that effectuates a change in a spread in ion energy at a wafer.

52. The method of claim 51, wherein applying the non-sinusoidal voltage waveform comprises generating a voltage waveform comprising a plurality of sinusoidal harmonics,
wherein the plurality of sinusoidal harmonics includes a 400 kHz fundamental harmonic and up and including to 10^{th} harmonic.

53. The method of claim 51, wherein applying the non-sinusoidal voltage waveform further comprises: a positive period, a negative period, and a duty cycle between 0-100%.
